(19) United States
(12) Patent Application Publication
(10) Pub. No.: US 2015/0197874 A1
(43) Pub. Date: Jul. 16, 2015

(54) DEVICE FOR GROWING MONOCRYSTALLINE SILICON AND METHOD FOR MANUFACTURING THE SAME

(71) Applicant: LG SILTRON INCORPORATED, Gumi-si, Gyeongsangbuk-do (KR)

(72) Inventors: Jong Min Kang, Gumi-si (KR); Se Geun Ha, Gumi-si (KR)

(21) Appl. No.: 14/411,365

(22) PCT Filed: Jul. 8, 2013
(86) PCT No.: PCT/KR2013/006030

§ 371 Date: Dec. 24, 2014

(30) Foreign Application Priority Data
Jul. 18, 2012 (KR) 10-2012-0078169

(51) Int. Cl. C30B 15/26; C30B 29/06

(52) U.S. Cl. CPC C30B 15/26; C30B 29/06

(57) ABSTRACT

One embodiment comprises: a crucible for holding a silicon melt; a heat shield for surrounding monocrystalline silicon which is grown from the silicon melt; a thermal image capturing portion for capturing a shoulder, which is grown by means of a shouldering process, and obtaining thermal image data as a result of the image capturing; and a control portion for calculating the weight of the shoulder by using the thermal image data, and controlling the raising or lowering the crucible on the basis of the weight of the shoulder that is calculated.

### TECHNICAL FIELD

Embodiments relate to devices of growing monocrystalline silicon and methods of manufacturing monocrystalline silicon.

### BACKGROUND ART

Generally, monocrystalline silicon wafers used as semiconductor device materials may be manufactured by slicing monocrystalline silicon ingots made by Czochralski (CZ) methods.

Czochralski growth of monocrystalline silicon ingots may include silicon melt preparation, necking, shouldering, body growing, and tailing processes.

A silicon melt preparation process is a process of stacking polycrystalline silicon and a dopant one above another within a quartz crucible and melting the polycrystalline silicon and dopant using heat radiated from a heater that is installed around a sidewall of the quartz crucible to prepare a silicon melt (SM).

A necking process is a process of dipping a seed crystal, which is a growth source of a monocrystalline silicon ingot, into a surface of the silicon melt to grow a thin and long crystal from the seed crystal.

A shouldering process is a process of growing the crystal such that a diameter of the monocrystalline silicon ingot gradually increases to finally reach a target diameter.

A body growing process is a process of growing the monocrystalline silicon ingot having a given target diameter to attain a desired length.

A tailing process is a process of gradually reducing the diameter of the monocrystalline silicon ingot by rotating the quartz crucible at a high velocity, so as to separate the ingot from the silicon melt, completing growth of the monocrystalline silicon ingot.

### DISCLOSURE

### Technical Problem

Embodiments provide devices of growing monocrystalline silicon and methods of manufacturing monocrystalline silicon, which enable compensation of a melt gap error caused by a shouldering process, thereby achieving consistent quality reproducibility and stability of monocrystalline silicon.

### Technical Solution

In one embodiment, a device of growing monocrystalline silicon, includes a crucible configured to receive a silicon melt, a heat shield configured to surround monocrystalline silicon grown from the silicon melt, an image capture unit configured to capture an image of a shoulder grown by shouldering process and to acquire image data based on the captured result, and a controller configured to calculate a weight of the shoulder using the image data and to regulate rising and lowering of the crucible based on the calculated weight of the shoulder.

The device of growing monocrystalline silicon may further include a length measurement unit configured to measure a length of the grown shoulder and to provide the controller with the measured length of the shoulder.

The controller may be configured to calculate a diameter of the shoulder using the image data and to calculate a weight of the shoulder using the calculated diameter of the shoulder, the length of the shoulder provided by the length measurement unit, and a density of the shoulder.

The controller may be configured to calculate a diameter of the shoulder using the image data provided by the image capture unit whenever the length of the shoulder increases by a predetermined increment.

The controller may be configured to complete regulation of the rising and lowering of the crucible after the shouldering process ends and before a body growing process begins. The controller may be configured to set a correction time and a first velocity based on the calculated weight of the shoulder and to raise the crucible at the first velocity for the correction time when a body growing process begins.

In accordance with another embodiment, a method of manufacturing monocrystalline silicon includes capturing an image of a shoulder and then acquiring image data based on the captured result, the shoulder being monocrystalline silicon grown from a silicon melt received in a chamber by a shouldering process, and the chamber incorporating a crucible configured to receive the silicon melt and a heat shield configured to block radiation of heat, calculating a weight of the shoulder using the image data, and compensating for a melt gap between a surface of the silicon melt and the heat shield based on the calculated weight of the shoulder.

The method of manufacturing monocrystalline silicon may further include measuring a length of the shoulder being grown and providing a controller with the measured length of the shoulder.

The calculating may include calculating a diameter of the shoulder using the image data, and calculating the weight of the shoulder using the calculated diameter of the shoulder, the measured diameter of the shoulder, and a density of the shoulder.

The calculating may include calculating a diameter of the shoulder using the image data whenever the length of the diameter increases by a predetermined increment, and accumulating weights of the shoulder calculated on a predetermined increment basis.

The method of manufacturing monocrystalline silicon may further include growing a body of the monocrystalline silicon via a body growing process after the shouldering process ends, and the compensating may be performed after the shouldering process ends and before the body growing process begins, or may be performed during the body growing process.

The compensating, performed during the body growing process, may include setting a correction time and a first velocity based on the calculated weight of the shoulder, raising the crucible at the first velocity for the correction time to compensate for the melt gap when the body growing process begins, and raising the crucible at a second velocity when the correction time has passed.

The first velocity may be a sum of the second velocity and a third velocity, the second velocity may be within a range of 0.4 mm/min to 0.7 mm/min, and the third velocity may be within a range of 0.01 mm/min to 0.1 mm/min.

### Advantageous Effects

Embodiments may achieve consistent quality reproducibility and stability of monocrystalline silicon.

### DESCRIPTION OF DRAWINGS

FIG. 1 is a sectional view showing a device of growing monocrystalline silicon according to an embodiment.

FIG. 2 is an enlarged view of a shoulder shown in FIG. 1.

FIG. 3a is a view showing a melt gap before a shouldering process.

FIG. 3b is a view showing a melt gap after a shouldering process.

FIG. 4 is a view showing a diameter of the shoulder measured whenever a length of the shoulder shown in FIG. 1 increases by a predetermined increment.

FIG. 5 is a view showing simulation results calculating a weight of the shoulder using image data provided by an image capture unit.

FIG. 6 is a flowchart of melt gap compensation with regard to manufacture of monocrystalline silicon according to an embodiment.

FIG. 7 is a flowchart showing one embodiment shoulder weight calculation shown in FIG. 6.

FIG. 8 is a view showing one embodiment of shoulder diameter calculation shown in FIG. 7.

FIG. 9 is flowchart showing one embodiment of shoulder weight calculation shown in FIG. 6.

FIG. 10 is a flowchart showing another embodiment of shoulder weight calculation shown in FIG. 6.

FIG. 11 is a view showing one embodiment of melt gap compensation shown in FIG. 6.

FIG. 12 is a view showing another embodiment of melt gap compensation shown in FIG. 6.

### BEST MODE

Hereinafter, embodiments will be clearly revealed via description thereof with reference to the accompanying drawings. In the following description of the embodiments, it will be understood that, when an element such as a layer (film), region, pattern, or structure is referred to as being “on” or “under” another element, it can be “directly” on or under another element or can be “indirectly” formed such that an intervening element may also be present. In addition, it will also be understood that criteria of on or under is on the basis of the drawing.

In the drawings, dimensions of layers are exaggerated, omitted or schematically illustrated for clarity and description convenience. In addition, dimensions of constituent elements do not entirely reflect actual dimensions. Wherever possible, the same reference numbers will be used throughout the drawings to refer to the same or like parts. Hereinafter, a device of growing monocrystalline silicon and a method of manufacturing monocrystalline silicon according to the embodiments will be described with reference to the accompanying drawings.

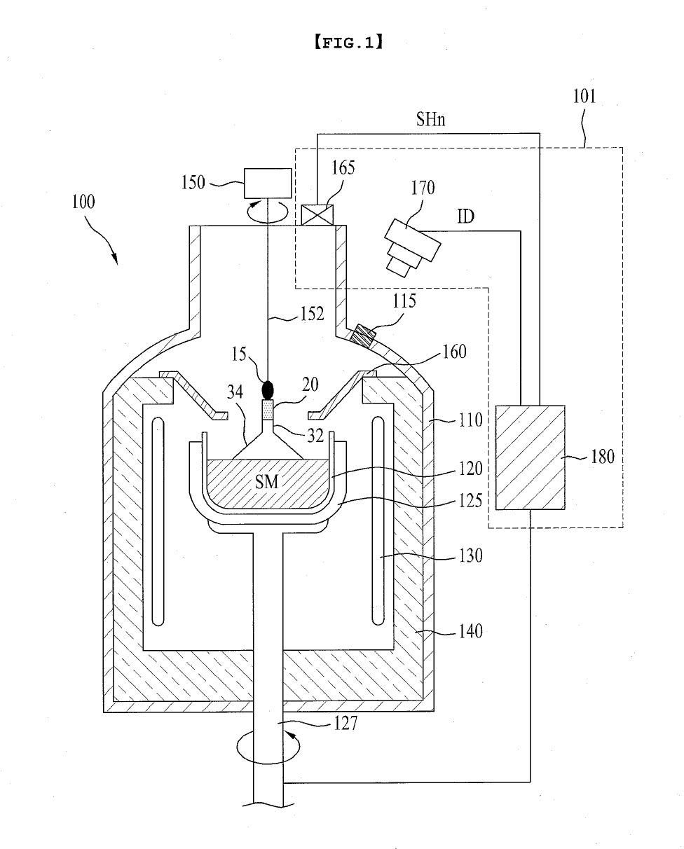

FIG. 1 is a sectional view showing a device of growing monocrystalline silicon, designated by reference numeral 100, according to an embodiment.

Referring to FIG. 1, the device of growing monocrystalline silicon 100 includes a chamber 110, a crucible 120, a crucible support member 125, a lifting unit 127, a heater 130, a thermal insulator 140, a pulling member 150, a cable 152, a heat shield 160, and a melt gap control system 101. In addition, the melt gap control system 101 may include a length measurement unit 165, an image capture unit 170, and a controller 180.

The chamber 110 is a space in which a monocrystalline (single-crystal) silicon ingot for a silicon wafer that is used as a material of electronic components, such as semiconductor, etc., is grown. The chamber may have at least one window 115 to allow the image capture unit 170 to capture an image of the interior of the chamber 110.

The crucible 120 may be installed in the chamber 110 and configured to receive a high-temperature silicon melt SM. The crucible may be formed of quartz without being limited thereto. The crucible support member 125 may surround an outer circumference of the crucible 120 to support the crucible 120. The crucible support member 125 may be formed of graphite without being limited thereto.

The lifting unit 127 may be located under the crucible support member 125 and serve not only to rotate the crucible 120 and the crucible support member 125, but also to raise or lower the crucible 120.

The heater 130 may be installed within the chamber 110 to surround a sidewall of the crucible 120 and serve to heat the crucible 120. The heater 130 may cause a high-purity polycrystalline silicon lump stacked in the crucible 120 to be melted into the silicon melt SM.

The thermal insulator 140 may be installed within the chamber 110 at a position around the heater 130 and serve to prevent leakage of heat generated in the heater 130.

The pulling member 150 may be installed above the crucible 120 to pull the cable 152. A seed chuck 15 may be connected to one end of the cable 152 and, in turn, a seed crystal 20 may be coupled to the seed chuck 15. The seed crystal 20 may be dipped into the silicon melt SM within the crucible 120.

The crucible support member 125 and the crucible 120 are rotated by the lifting unit 127 and the pulling member 150 may pull the cable 152. As the cable 152 is pulled, monocrystalline silicon may be grown from the silicon melt SM received in the crucible 120.

The heat shield 160 may prevent radiation of heat from the silicon melt SM to the monocrystalline silicon that is being grown and also prevent impurities (e.g., CO gas) generated in the heater 130 from entering the monocrystalline silicon.

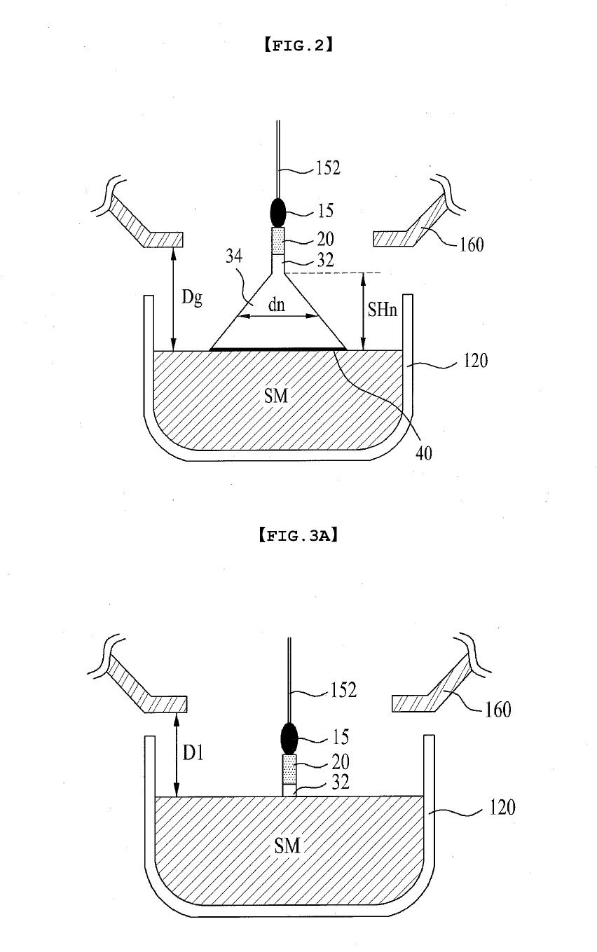

FIG. 2 is an enlarged view of a shoulder 34 shown in FIG. 1.

Referring to FIG. 2, before a shouldering process, a thin and long monocrystalline silicon ingot may be grown from the seed crystal 20 in a necking process. Hereinafter, a monocrystalline silicon portion grown by the necking process will be referred to as a “neck 32”.

Then, the monocrystalline silicon ingot may be grown such that a diameter thereof gradually increases to a target diameter in a shouldering process. Such a monocrystalline silicon portion having gradually increasing diameter is referred to as the “shoulder 34”.

A distance between a lower end of the heat shield 160 and a surface of the silicon melt SM is referred to as a “melt gap Dg”. It is necessary to maintain a constant melt gap during monocrystalline silicon growth for enhancement in the quality and productivity of the monocrystalline silicon ingot. There may be an error between a melt gap before the shouldering process and a melt gap after the shouldering process because the shouldering process causes the silicon melt SM to be solidified to the shoulder 34.

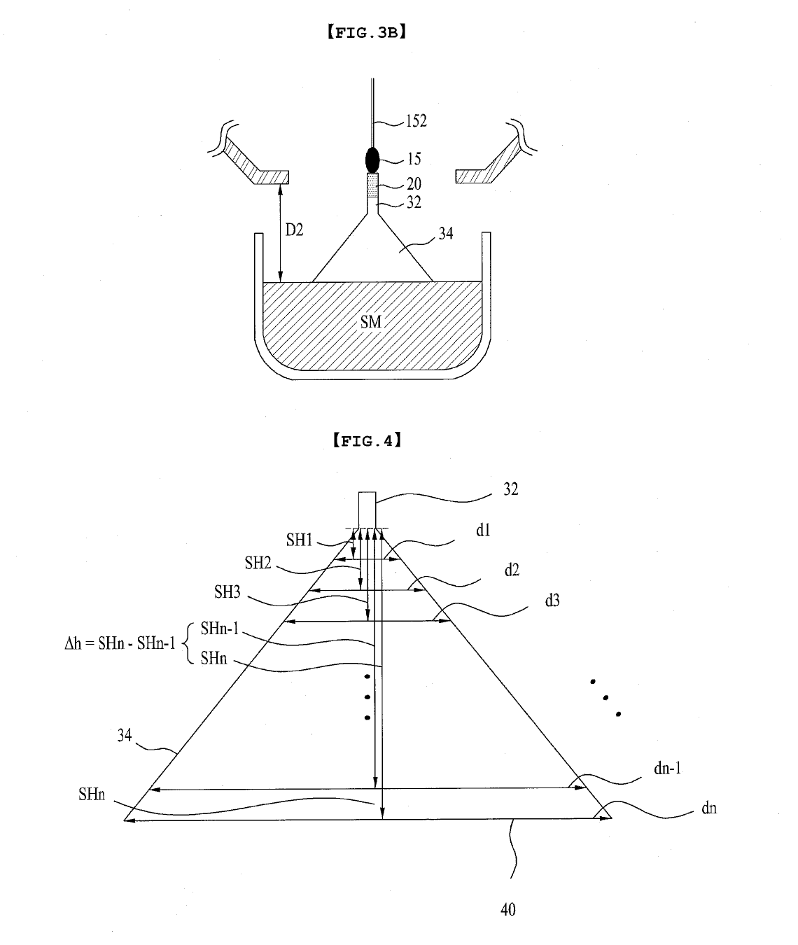

FIG. 3a is a view showing a melt gap D1 before the shouldering process and FIG. 3b is a view showing a melt gap D2 after the shouldering process. Referring to FIGS. 3A and 3B, there may be an error (e.g., 2 mm-4 mm) between the melt gap D1 before the shouldering process and the melt gap D2 after the shouldering process.

The melt gap control system 101 may correct a melt gap error caused by the shouldering process, i.e. an error between melt gaps before and after the shouldering process to maintain a constant melt gap before and after the shouldering process, thereby achieving consistent quality reproducibility and stability of monocrystalline silicon.

The measurement unit 165 may be installed to at least one of an interior location, exterior location, and outer wall surface of the chamber 110 and serve to measure a length SHn of the shoulder 34 grown by the shouldering process. The length SHn of the shoulder 34 measured by the length measurement unit 165 may be provided to the controller 180.

For example, the length measurement unit 165 may indirectly measure a length of the ingot by detecting a rotation angle of a shaft using an encoder.

Alternatively, the length measurement unit 165 may measure the length SHn of the shoulder 34 by measuring a distance to a top surface of the seed chuck (not shown), on which the seed crystal 20 is mounted, using a laser displacement measurement sensor.

The image capture unit 170 may capture an image of monocrystalline silicon that is being grown within the chamber 110 through the window 115. The image capture unit 170 may include a charge coupled device (CCD) image pickup device or a complementary metal oxide semiconductor (CMOS) image pickup device for one or more times of photoelectric conversion. While FIG. 1 shows one image pickup device, the embodiment is not limited thereto, and a plurality of image pickup devices may be used to capture an image of the monocrystalline silicon that is being grown within the chamber 110.

The image capture unit 170 may capture an image of an interface 40 where the shoulder 34 grown by the shouldering process comes into contact with the silicon melt SM received in the crucible 120, and acquire image data (ID) based on the captured result. In this case, an image of the interface 40 based on the acquired image data D may be a meniscus and a meniscus of the shoulder 34 acquired by the image capture unit 170 may be represented as a bright ring.

The image capture unit 170 may capture an image of the interface 40 where the shoulder 34 comes into contact with the silicon melt SM received in the crucible 120 continuously in real time or periodically by beginning image capture when the shouldering process begins.

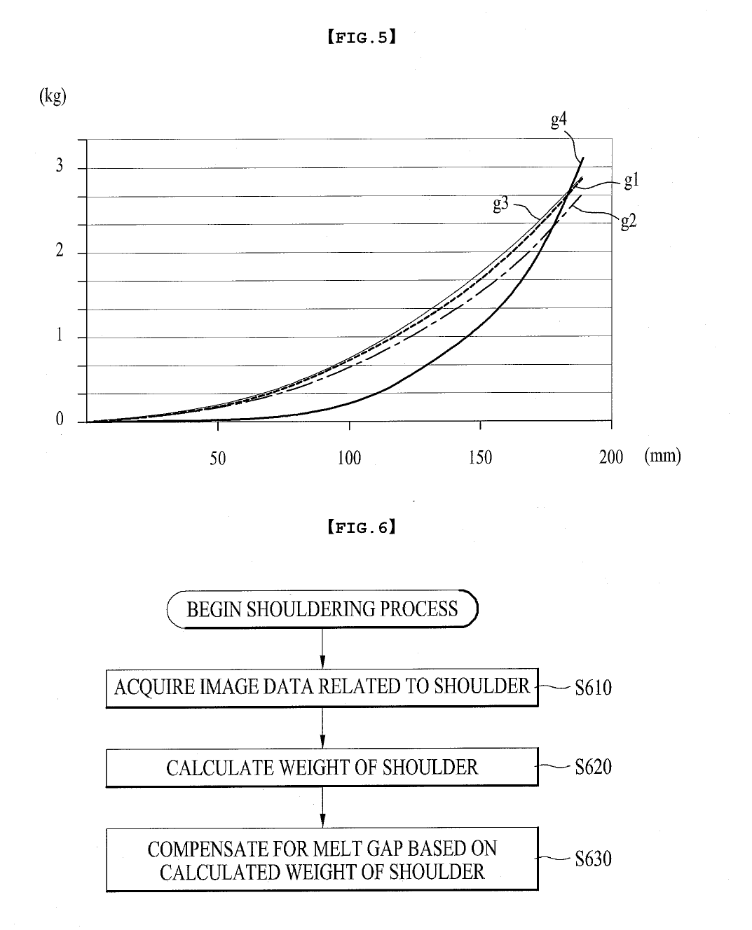

The image capture unit 170 may capture an image in real time and provide the controller 180 with image data ID when the length SHn of the shoulder 34 that is being grown increases by a predetermined increment (Δh=SHₙ−SHₙ₋₁) (see FIG. 4). For example, the image capture unit 170 may provide the controller 180 with the image data D when the length SHn of the shoulder 34 increases by 1 mm.

Alternatively, the image capture unit 170 may capture an image of the interface 40 to acquire image data ID of the shoulder 34 whenever the length SHn of the shoulder 34 that is being grown increases by a predetermined increment (Δh=SHₙ−SHₙ₋₁), and provide the controller 180 with the acquired image data ID.

For example, the image capture unit 170 may capture an image of the interface 40 to acquire image data ID of the shoulder 34 whenever the length SHn of the shoulder 34 increases by 1 mm, and provide the controller 180 with the acquired image data D.

The controller 180 may calculate a diameter dn of the shoulder 34 using the length SHn of the shoulder 34 provided by the length measurement unit 165 and the image data ID provided by the image capture unit 170.

For example, the controller 180 may calculate the diameter dn of the shoulder 34 by processing and analyzing the image data ID. The controller 180 may perform image binarization on the image data ID provided by the image capture unit 170 on the basis of a prescribed threshold value, thereby generating binary image data. In this case, the prescribed threshold value may be a specific value within a range of 1 to 255 with respect to a grayscale image that may have brightness information of 8 bit, i.e. 256 level, or may be within a given numerical value range. This binary image data may represent only an image of the interface 40.

Image binarization used in this case may be divided into global methods and local methods. Examples of global methods may include a method using dispersion between two classes, method using entropy, method using histogram deformation, and method using maintenance of a moment. Examples of local methods may include a method using a window area (i.e. method using a threshold value or comparison), local contrast technique, logical level technique, object attribute thresholding (OAT) method, local intensity gradient technique, and dynamic threshold algorithm.

The controller 180 may extract a coordinate sample (e.g., a pixel coordinate sample of an image) with respect to the interface 40 from the binary image data, and calculate the diameter do of the shoulder 34 from the extracted coordinate sample.

In another embodiment, the controller 180 may calculate the diameter dn (n≧1) of the shoulder 34 whenever the length SHn of the shoulder 34 that is being grown increases by a predetermined increment.

FIG. 4 is a view showing the diameter dn of the shoulder measured whenever the length of the shoulder 34 shown in FIG. 1 increases by a predetermined increment (Δh=SHₙ−SHₙ₋₁). Referring to FIG. 4, the controller 180 may judge whether the length SHn of the shoulder 34 increases by a predetermined increment Δh based on the length SHn of the shoulder 34 provided by the length measurement unit 165. In this case, the predetermined increment Δh may have a constant value (e.g., 1 mm), or may be variable.

As described above, the controller 180 may measure the diameter dn of the shoulder 34 at a lower surface of the shoulder 34 using the image data ID provided by the image capture unit 170 whenever the length of the shoulder 34 increases by the predetermined increment Δh.

The controller 180 may calculate a weight of the entire shoulder 34 grown in the shouldering process using the length SHn of the shoulder 34, a density of the shoulder 34, and the calculated diameter dn of the shoulder 34. For example, the controller 180 may calculate a volume of the shoulder 34 using the length SHn of the shoulder 34 and the diameter dn of the shoulder 34, and calculate a weight of the shoulder 34 using the calculated volume and the density of the shoulder 34. In this case, the density of the shoulder 34 is a density of silicon and may have a known value, e.g., 2.33 g/cm³.

Alternatively, the controller 180 may calculate the diameter dn of the shoulder 34 whenever the length SHn of the shoulder 34 increases by a predetermined increment Δh, and calculate a weight of an increased portion of the shoulder 34 using the calculated diameter dn (n≧1) of the shoulder, the predetermined increment Δh, and the density of the shoulder 34. Then, the controller 180 may calculate a weight of the entire shoulder 34 grown in the shouldering process by accumulating weight values of all increased portions of the shoulder 34.

In another embodiment, the controller 180 may directly calculate a weight of the shoulder 34 from the image data ID acquired by the image capture unit 170.

FIG. 5 is a view showing simulation results of calculating a weight of the shoulder 34 using the image data ID provided by the image capture unit 170. The x-axis indicates a length of the shoulder 34 and the y-axis indicates a weight of the shoulder 34.

Referring to FIG. 5, g1 indicates a real weight of the shoulder 34. g2 indicates a weight W1 of the shoulder 34 calculated by Equation 1, g3 indicates a weight W2 of the shoulder 34 calculated by Equation 2, and g4 indicates a weight W3 of the shoulder 34 calculated by Equation 3.

g2=ID²×0.0011 Equation 1

g3=ID²×0.0012 Equation 2

g4=ID²×0.0013 Equation 3

Here, ID is the image data ID provided by the image capture unit 170 to the controller 180 whenever the length SHn of the shoulder 34 increases by a predetermined increment (Δh=1 mm).

It will be appreciated that the weight g3 of the shoulder 34 calculated by Equation 2 is close to the real weight g1 of the shoulder 34. Accordingly, in the embodiment, the weight of the shoulder 34 may be calculated using the image data ID provided by the image capture unit 170 and Equation 2 whenever the length SHn of the shoulder 34 increases by the predetermined increment (e.g., Δh=1).

Here, the predetermined increment Δh may be within a range of 0.5 mm to 1.5 mm and, preferably, 1 mm. When the predetermined increment Δh is below 0.5 mm, calculation complexity may cause load of the controller 180 or an excessively increased calculation time. When the predetermined increment Δh exceeds 1.5 mm, there may be a great error between the real weight of the shoulder 34 and the calculated weight.

The controller 180 may calculate the amount of a solidified melt of the silicon melt SM during the shouldering process based on the calculated weight of the shoulder 34.

Then, the controller 180 may calculate a melt gap D2 after the shouldering process using the calculated amount of the solidified melt or a melt gap change value (ΔD=D2−D1) before and after the shouldering process.

The controller 180 may control the lifting unit 127 to control a position of the crucible 120 based on the calculated amount of the solidified melt. Then, the melt gap error generated after the shouldering process may be compensated as the lifting unit 127 raises or lowers the crucible 120 under control of the controller 180.

Alternatively, the controller 180 may control the lifting unit 127 to compensate for the melt gap error generated after the shouldering process based on the calculated melt gap after the shouldering process or the melt gap change value (ΔD=D2−D1) before and after the shouldering process.

The controller 180 may complete compensation of the melt gap error caused by the shouldering process prior to beginning a body growing process. For example, the controller 180 may control the lifting unit 127 to raise the crucible 120 by a distance corresponding to the melt gap change value AD before and after the shouldering process, prior to beginning a body growing process.

In another embodiment, the controller 180 may control the lifting unit 127 to compensate for the melt gap error caused by the shouldering process during implementation of a body growing process.

For example, the controller 180 may compensate for the melt gap error caused by the shouldering process by setting an error correction time T based on the calculated weight of the shoulder 34 and raising the crucible at a first velocity v1 for the set error correction time T during a body growing process.

In this case, the first velocity v1 may be a sum of a second velocity v2 and a third velocity v3. Here, the crucible 120 may be raised at the second velocity v2 during a body growing process in order to correct the melt gap error caused by the body growing process. For example, the second velocity v2 may be within a range of 0.4 mm/min to 0.7 mm/min.

The third velocity v3 may be a velocity that is added to the second velocity v2 in order to compensate for the melt gap error caused via the shouldering process. The third velocity v3 may be within a range of 0.01 mm/min to 0.1 mm/min and, preferably, 0.05 mm/min.

Accordingly, in the embodiment, the controller 180 may raise the crucible 120 at the first velocity v1 for the error correction time T after the body growing process begins so as simultaneously correct a melt gap error caused by the shouldering process and a melt gap error caused by the body growing process and then raise the crucible 120 at the second velocity v2 during the body growing process after the error correction time T has passed so as to correct only a melt gap error caused by the body growing process.

The embodiment, as described above, may previously correct a melt gap error caused by the shouldering process, prior to beginning the body growing process or during implementation of the body growing process, thereby achieving consistent quality reproducibility and stability of the monocrystalline silicon ingot.

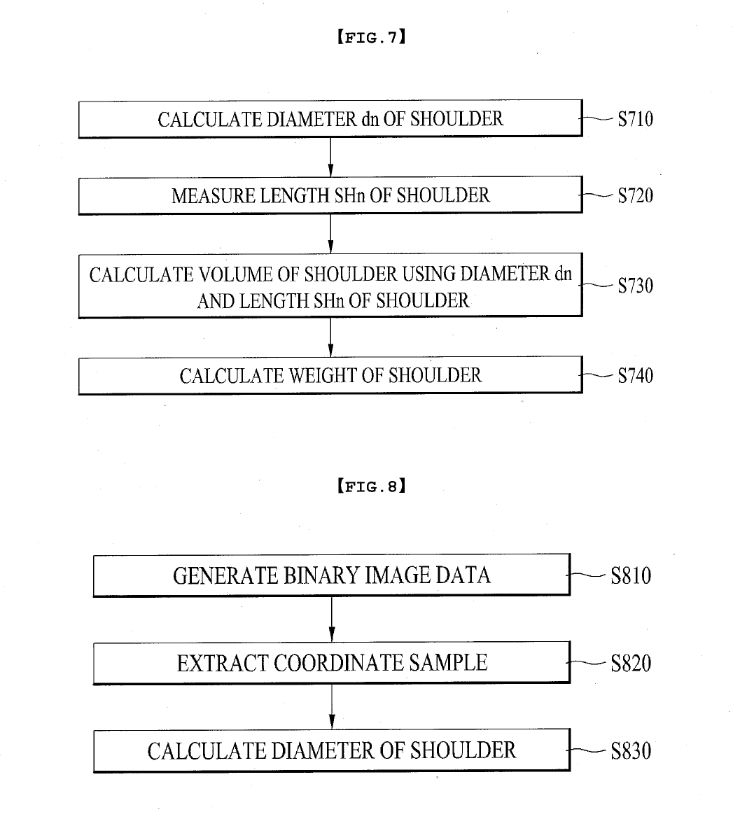

FIG. 6 is a flowchart of melt gap compensation with regard to manufacture of monocrystalline silicon according to an embodiment. Hereinafter, melt gap compensation will be described with reference to the monocrystalline silicon manufacture device as exemplarily shown in FIGS. 1 and 2.

Referring to FIG. 6, first, an image of the interface 40 where the shoulder 34 comes into contact with the silicon melt SM within the crucible 120 is captured using a CCD camera or the like simultaneously with beginning of the shouldering process, and image data ID is acquired based on the captured result (S610).

Next, a weight of the shoulder 34 grown by the shouldering process is calculated using the image data ID (S620).

Next, a melt gap error caused by the shouldering process is compensated based on the calculated weight of the shoulder 34 (S630).

FIG. 7 is a flowchart showing one embodiment of calculation for the weight of the shoulder 34 shown in FIG. 6.

Referring to FIG. 7, the diameter do of the shoulder 34 is calculated using the image data ID (S710). Next, the length SHn of the shoulder 34 that is being grown is measured by the length measurement unit 165 (S720).

For example, it will be appreciated that the image data ID may be provided whenever the length SHn of the shoulder 34 increases by a predetermined increment (Δh=SHₙ−SHₙ₋₁).

Next, a volume of the shoulder is calculated using the measured length SHn of the shoulder 34 and the calculated diameter Dn of the shoulder 34 (S730). Next, a weight of the entire shoulder 34 grown by the shouldering process is calculated using the calculated volume of the shoulder 34 and a density of the shoulder (e.g., a density of silicon) (S740).

In the case in which the image data ID is provided whenever the length SHn of the shoulder 34 increases by the predetermined increment (×h=SHₙ−SHₙ₋₁), the weight of the entire shoulder 34 may be calculated by calculating weights of respective increased shoulder portions and accumulating the calculated weights.

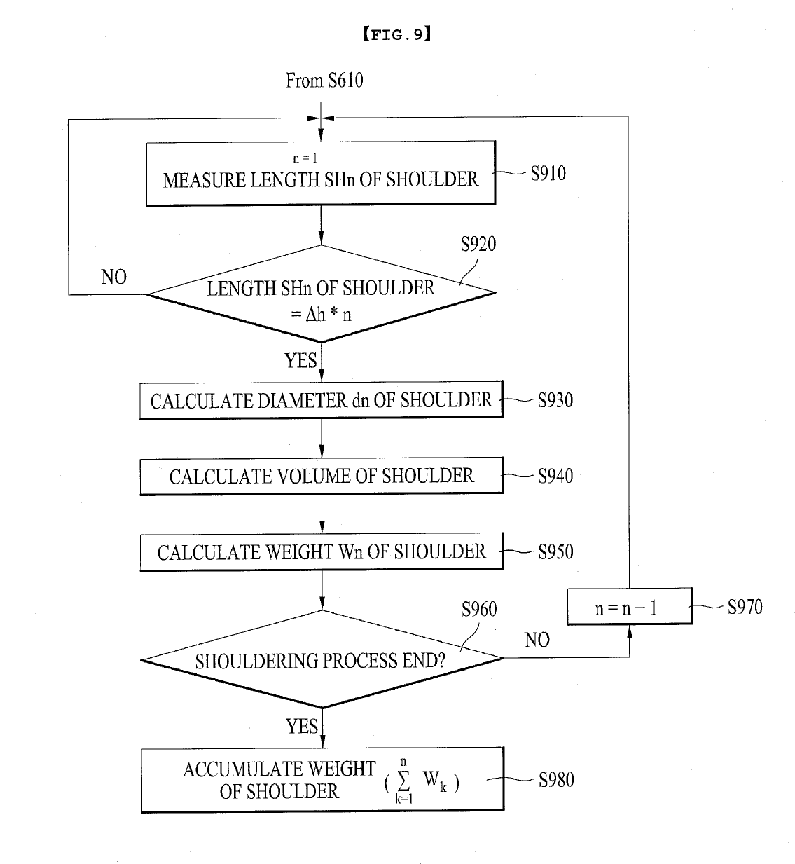

FIG. 8 is a view showing one embodiment of calculation for the diameter dn of the shoulder 34 shown in FIG. 7. Referring to FIG. 8, the image data ID is converted via image binarization to produce binary image data (S810). The image binarization may be identical to the above description.

Next, a coordinate sample (e.g., a pixel coordinate sample of an image) with respect to the interface 40 is extracted from the binary image data (S820). Next, the diameter dn of the shoulder 34 is calculated from the extracted coordinate sample (S830).

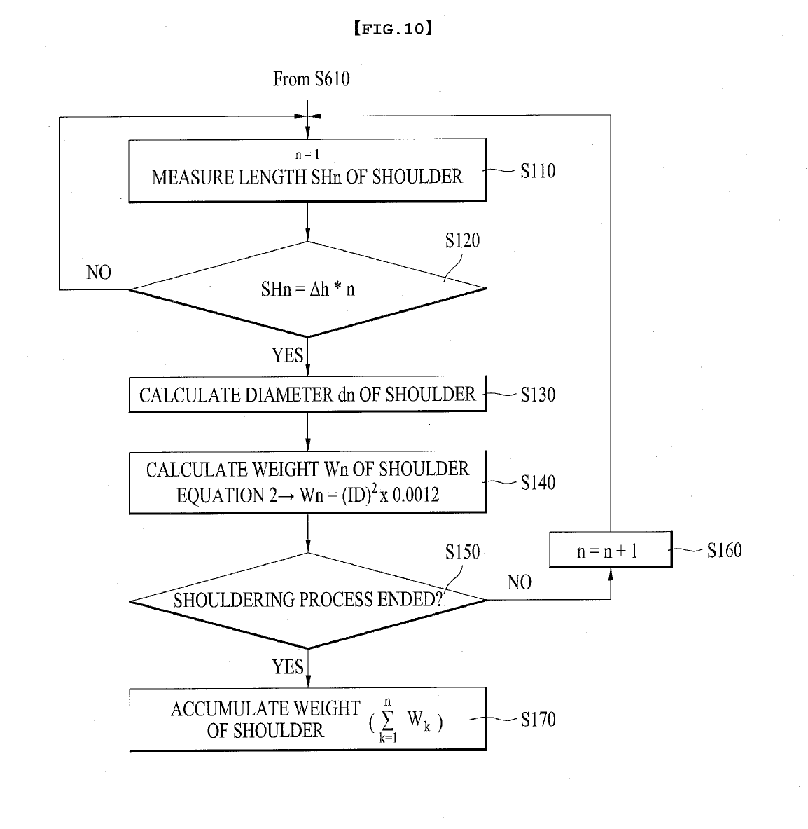

FIG. 9 is flowchart showing an embodiment calculation for the weight of the shoulder 34 shown in FIG. 6. Referring to FIG. 9, the length SHn of the shoulder 34 that is being grown is measured by the length measurement unit 165 (S910). In this case, an initial value of n may be set to 1, and SH₀ indicates the case in which a length of the shoulder is 0.

Next, it is judged whether the measured length SHn of the shoulder is equal to the predetermined increment (×h=SHₙ−SHₙ₋₁) multiplied by n (S920). In the case of SHn≠Δh×n, the length of the shoulder 34 grown by the shouldering process is continuously measured. In the case of SHn=Δh×n, the diameter dn of the shoulder 34 is calculated using the image data ID provided by the image capture unit 170 (S930).

Next, a volume of the shoulder 34 is calculated using the calculated diameter dn of the shoulder 34 and the measured length SHn of the shoulder 34 (S940). Next, a weight Wn of the shoulder 34 is calculated using the calculated volume of the shoulder 34 and a density of the shoulder 34 (S950).

Next, it is judged, using the calculated diameter dn of the shoulder 34, whether or not to end the shouldering process. More specifically, it is judged whether the calculated diameter dn of the shoulder 34 is equal to a target diameter. For example, the target diameter may be a desired diameter of a body portion of the monocrystalline silicon ingot.

When the calculated diameter dn of the shoulder 34 is not equal to the target diameter, the shouldering process does not end. In this case, a value of n is updated to n+1 (S970), and the above-described steps S910 to 5960 are repeated.

When the calculated diameter dn of the shoulder 34 is equal to the target diameter, the shouldering process ends. In this case, a weight of the entire shoulder grown by the shouldering process is calculated by accumulating all weight values of respective portions of the shoulder 34 calculated on a per predetermined increment Δh basis (S980).

FIG. 10 is a flowchart showing another embodiment of calculation for the weight of the shoulder 34 shown in FIG. 6.

Referring to FIG. 10, the length SHn of the shoulder that is being grown is measured by the length measurement unit 165 (S110), and it is judged whether the measured length SHn of the shoulder is equal to the predetermined increment (×h=SHₙ−SHₙ₋₁) multiplied by n (S120). In this case, an initial value of n may be set to 1, and SH₀ indicates the case in which a length of the shoulder is 0. In the case of SHn≠Δh×n, the length of the shoulder 34 grown by the shouldering process is continuously measured.

In the case of SHn=Δh×n, the diameter dn of the shoulder 34 is calculated (S130), and a weight Wn of the shoulder is calculated using the image data ID and Equation 2 (S140).

Next, it is judged whether or not to end the shouldering process using the calculated diameter dn of the shoulder 34 (S150). More specifically, when the calculated diameter dn of the shoulder 34 is not equal to a target diameter, a value of n is updated to n+1 (S160), and the above-described steps S110 to S150 are repeated.

When the calculated diameter dn of the shoulder 34 is equal to the target diameter, a weight of the entire shoulder grown by the shouldering process is calculated by accumulating all weight values of respective portions of the shoulder 34 calculated on a per predetermined increment Δh basis (S170).

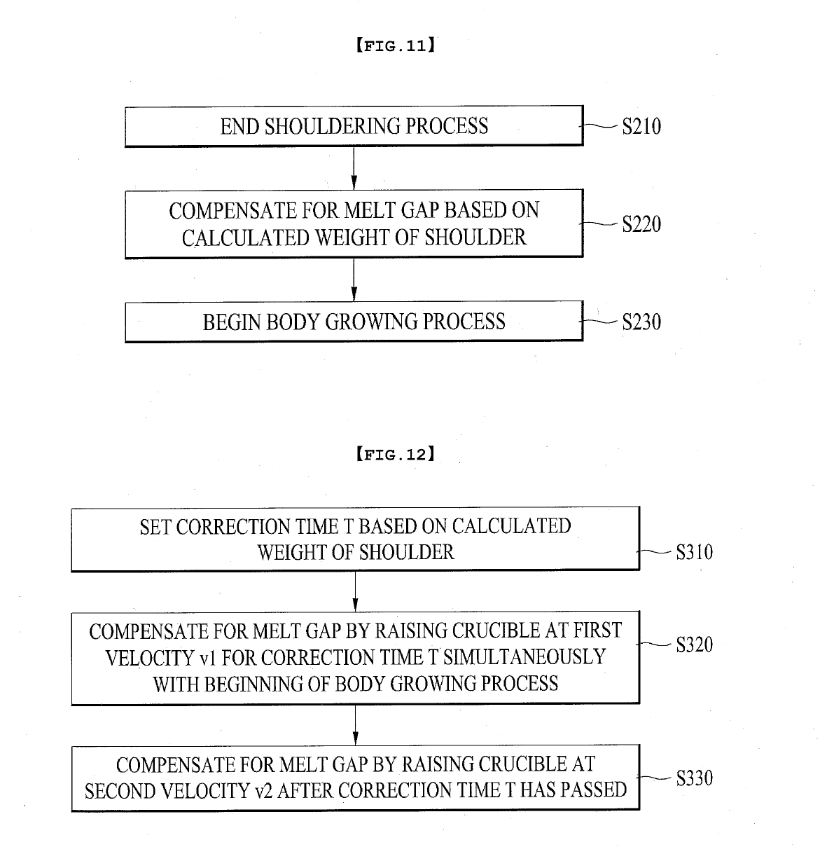

FIG. 11 is a view showing one embodiment of melt gap compensation S630 shown in FIG. 6.

Referring to FIG. 11, when the shouldering process ends (S210), a melt gap is compensated based on the calculated weight of the shoulder (S220). More specifically, the amount of a solidified melt of the silicon melt SM is calculated based on the calculated weight of the shoulder 34 during the shouldering process, and a melt gap D2 after the shouldering process or a melt gap change value (ΔD=D2−D1) before and after the shouldering process is calculated using the calculated amount of the solidified melt. Then, a melt gap error corresponding to the melt gap change value (AD) before and after the shouldering process may be compensated.

After compensation of the melt gap error, the body growing process of the monocrystalline silicon ingot begins (S230). Compensation of the melt gap error caused by the shouldering process shown in FIG. 11 may be performed after completion of the shouldering process or prior to beginning the body growing process.

FIG. 12 is a view showing another embodiment of melt gap compensation S630 shown in FIG. 6.

Referring to FIG. 12, a correction time T and a first velocity v1 are set based on the calculated weight of the shoulder (S310).

The melt gap error caused by the shouldering process is compensated by raising the crucible 120 at the first velocity v1 for the correction time T simultaneously with beginning of the body growing process (S310).

The melt gap error may be caused by the body growing process. The melt gap error caused by the body growing process may be compensated by raising the crucible 120 at the second velocity v2 during implementation of the body growing process (S320).

The first velocity v1 is faster than the second velocity v2. For example, v1=v2+v3. In this case, the second velocity v2 may be within a range of 0.4 mm/min to 0.7 mm/min. In addition, the third velocity v3 is added to the second velocity v2 to compensate for the melt gap error caused by the shouldering process. For example, the third velocity v3 may be within a range of 0.01 mm/min to 0.1 mm/min and, preferably, 0.05 mm/min.

The crucible 120 may be raised at the second velocity v2 after the correction time T has passed, in order to compensate for the melt gap error caused by the body growing process (S330).

Compensation of the melt gap error caused by the shouldering process shown in FIG. 12 may be performed during implementation of the body growing process.

Characteristics, configurations, effects, and the like described in the above embodiments are included in at least one embodiment of the present invention, but are not essentially limited to only one embodiment. It will be apparent to those skilled in the art that various modifications or combinations of the characteristics, configurations, effects, and the like exemplified in the respective embodiments can be made. Thus, it should be analyzed that all contents related to these modifications or combinations belong to the range of the present invention.

### INDUSTRIAL APPLICABILITY

Embodiments may be used in monocrystalline silicon growth for fabrication of wafers.

1. A device of growing monocrystalline silicon, the device comprising:
a crucible configured to receive a silicon melt;
a heat shield configured to surround monocrystalline silicon grown from the silicon melt;
an image capture unit configured to capture an image of a shoulder grown by a shouldering process and to acquire image data based on the captured result; and
a controller configured to calculate a weight of the shoulder using the image data and to regulate rising and lowering of the crucible based on the calculated weight of the shoulder.

2. The device according to claim 1, further comprising a length measurement unit configured to measure a length of the grown shoulder and to provide the controller with the measured length of the shoulder.

3. The device according to claim 2, wherein the controller is configured to calculate a diameter of the shoulder using the image data and to calculate a weight of the shoulder using the calculated diameter of the shoulder, the length of the shoulder provided by the length measurement unit, and a density of the shoulder.

4. The device according to claim 3, wherein the controller is configured to calculate a diameter of the shoulder using the image data provided by the image capture unit whenever the length of the shoulder increases by a predetermined increment.

5. The device according to claim 1, wherein the controller is configured to complete regulation of the rising and lowering of the crucible after the shouldering process ends and before a body growing process begins.

6. The device according to claim 1, wherein the controller is configured to set a correction time and a first velocity based on the calculated weight of the shoulder and to raise the crucible at the first velocity for the correction time when a body growing process begins.

7. A method of manufacturing monocrystalline silicon, the method comprising:
capturing an image of a shoulder and then acquiring image data based on the captured result, the shoulder being monocrystalline silicon grown from a silicon melt received in a chamber by a shouldering process, and the chamber incorporating a crucible configured to receive the silicon melt and a heat shield configured to block radiation of heat;
calculating a weight of the shoulder using the image data; and
compensating for a melt gap between a surface of the silicon melt and the heat shield based on the calculated weight of the shoulder.

8. The method according to claim 7, further comprising measuring a length of the shoulder being grown and providing a controller with the measured length of the shoulder.

9. The method according to claim 8, wherein the calculating includes:
calculating a diameter of the shoulder using the image data; and
calculating the weight of the shoulder using the calculated diameter of the shoulder, the measured diameter of the shoulder, and a density of the shoulder.

10. The method according to claim 9, wherein the calculating includes:
calculating a diameter of the shoulder using the image data whenever the length of the diameter increases by a predetermined increment; and
accumulating weights of the shoulder calculated on a per predetermined increment basis.

11. The method according to claim 7, further comprising growing a body of the monocrystalline silicon via a body growing process after the shouldering process ends,
wherein the compensating is performed after the shouldering process ends and before the body growing process begins.

12. The method according to claim 7, further comprising growing a body of the monocrystalline silicon via a body growing process after the shouldering process ends,
wherein the compensating is performed during the body growing process.

13. The method according to claim 12, wherein the compensating includes:
setting a correction time and a first velocity based on the calculated weight of the shoulder;
raising the crucible at the first velocity for the correction time to compensate for the melt gap when the body growing process begins; and
raising the crucible at a second velocity when the correction time has passed.

14. The method according to claim 13, wherein the first velocity is a sum of the second velocity and a third velocity, the second velocity is within a range of 0.4 mm/min to 0.7 mm/min, and the third velocity is within a range of 0.01 mm/min to 0.1 mm/min.
